(19) United States
(12) Patent Application Publication
(10) Pub. No.: US 2015/0069989 A1
(43) Pub. Date: Mar. 12, 2015

(54) ELECTRIC DEVICE AND CONTROL METHOD CAPABLE OF REGULATING DC CURRENT THROUGH A DEVICE

(71) Applicant: Leadtrend Technology Corporation, Hsinchu (TW)

(72) Inventor: Yeu Torng Yau, Hsinchu (TW)

(21) Appl. No.: 14/478,976

(22) Filed: Sep. 5, 2014

(30) Foreign Application Priority Data
Sep. 6, 2013 (TW) 102132128

(51) Int. Cl. H02M 3/158; H03F 3/45; H02M 1/08

(52) U.S. Cl. CPC H02M 3/158; H02M 1/08; H03F 3/45071
USPC 323/282

(57) ABSTRACT

An apparatus comprises an amplifier and a pulse-width modulator. The amplifier has a first input node coupled to receive a first voltage signal representing a current through the load, a second input node coupled to a reference voltage, and a first output node for providing an output signal. The amplifier has a differential gain. The pulse-width modulator, in response to the output signal, provides a PWM signal to a power switch which controls the current, thereby regulating the average current. The PWM signal is capable of defining an ON time and an OFF time. In response to the PWM signal, the differential gain is about 0 during the OFF time.

### CROSS-REFERENCE TO RELATED APPLICATION

This application claims priority to and the benefit of Taiwan Application Series Number 102132128 filed on Sep. 6, 2013, which is incorporated by reference in its entirety.

### BACKGROUND

The present disclosure relates generally to methods and apparatuses for regulating an average current through a load, more particularly to means for accurately controlling an average current through an LED string.

FIG. 1 demonstrates a buck converter 100, which is capable of being used in a backlight module of a LCD display panel, for driving LEDs to provide certain illumination. In the buck converter 100, connected in series between a high-voltage power line VIN and a ground power line GND are a LED string 106 with several LEDs, an inductor 108, a power switch 104, and a current sense resistor RCS, where the power switch 104 is controlled by an integrated circuit 102. A discharge diode 110 also connects the high-voltage power line VIN to the power switch 104, and provides a discharge path back to the high-voltage power line VIN when the power switch 104 is turned OFF. A filter capacitor 109 connects in parallel to the LED string 106, to substantially reduce the ripple in the voltage across and the current through the LED string 106.

The integrated circuit 102 has for example a controller 112 and a gate driver 114. Based upon the current sense voltage signal V_{CS}, the controller 112 provides a PWM signal S_{PWM}, which is level-shifted or amplified to become a gate-driving signal V_{G} with appropriate voltage for driving the power switch 104. FIG. 2 demonstrates the integrated circuit 102 in the art, including a SR register 116, a clock generator 118, a comparator 120, and a leading-edge blanking circuit 122.

The clock generator 118 periodically sets the SR register 116 to assert the PWM signal S_{PWM} and turn ON the power switch 104. When the PWM signal S_{WPM} is asserted, it starts an ON time T_{ON} as the power switch 104 is ON, performing a short circuit. In the beginning of an ON time T_{ON}, the leading-edge blanking circuit 122 prevents the current sense voltage signal V_{CS} from reaching the comparator 120 for a very short period of time, otherwise the initial high peak noise in the current sense voltage signal V_{CS} could deteriorate the control loop of the system. The comparator 120 compares the current sense voltage signal V_{CS} to a reference voltage V_{REF-OLD}.

The circuit architecture of the integrated circuit 102 in FIG. 2 can control the peak of the current sense voltage signal V_{CS}, making it about the value of the reference voltage V_{REF-OLD}. FIG. 3 shows some results under the control of the integrated circuit 102, where the current signal IL_{1-OLD}/IL_{2-OLD} represents the current through the inductor 108 whose inductance is L₁/L₂. During an ON time T_{ON} when the gate-driving signal V_{G} is “1” in logic, both the current signals IL_{1-OLD} and IL_{2-OLD} rise over time. In the opposite, during an OFF time T_{OFF} when the gate-driving signal V_{G} is “0” in logic, both the current signals IL_{1-OLD} and IL_{2-OLD} descend over time, as shown in FIG. 3. It is shown in FIG. 3 that the peaks of the current signals IL_{1-OLD} and IL_{2-OLD} are in common, about V_{REF-OLD/R}_{CS}, where R_{CS} is the resistance of the current sense resistor RCS. As the average current through the LED string 106 equals to the average current through the inductor 108, FIG. 3 demonstrates that the average current through the LED string 106 changes from ILED_{1-OLD} to ILED_{2-OLD} if the inductance of the inductor 108 varies from L₁ to L₂. Accordingly, the average current through the LED string 106, under the control of the integrated circuit 102, is not independent from the inductance of the inductor 108. In other words, the variation in the inductance of the inductor 108 will affect the brightness of the LED string 106, and this result is unwelcome in view of mass production.

### SUMMARY

Embodiments of the present invention provide an apparatus capable of regulating an average current through a load. The apparatus comprises an amplifier and a pulse-width modulator. The amplifier has a first input node coupled to receive a first voltage signal representing a current through the load, a second input node coupled to a reference voltage, and a first output node for providing an output signal. The amplifier has a differential gain. The pulse-width modulator, in response to the output signal, provides a PWM signal to a power switch which controls the current, thereby regulating the average current. The PWM signal is capable of defining an ON time and an OFF time. In response to the PWM signal, the differential gain is about 0 during the OFF time.

Embodiments of the present invention provide a control method for regulating an average current through a load. A first voltage signal is received to represent a current through the load. A reference voltage is provided. An output current signal is generated based on a differential transconductance gain and a difference between the first voltage signal and the reference voltage. a PWM signal is generated in response to the output current signal to regulate the average current. The PWM signal is capable of defining an ON time and an OFF time. The differential transcoductance gain is made to be about 0 during the OFF time.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIG. 1 demonstrates a buck converter in the art;

FIG. 2 demonstrates the integrated circuit in FIG. 1;

FIG. 3 shows some results under the control of the integrated circuit in FIG. 2;

FIG. 4 demonstrates an integrated circuit according to embodiments of the invention;

FIG. 5 shows waveforms of some signals in FIG. 4 while the integrated circuit in FIG. 1 is replaced by the integrated circuit in FIG. 4; and

FIG. 6 illustrates some results when the buck converter of FIG. 1 is under the control of the integrated circuit in FIG. 4.

### DETAILED DESCRIPTION

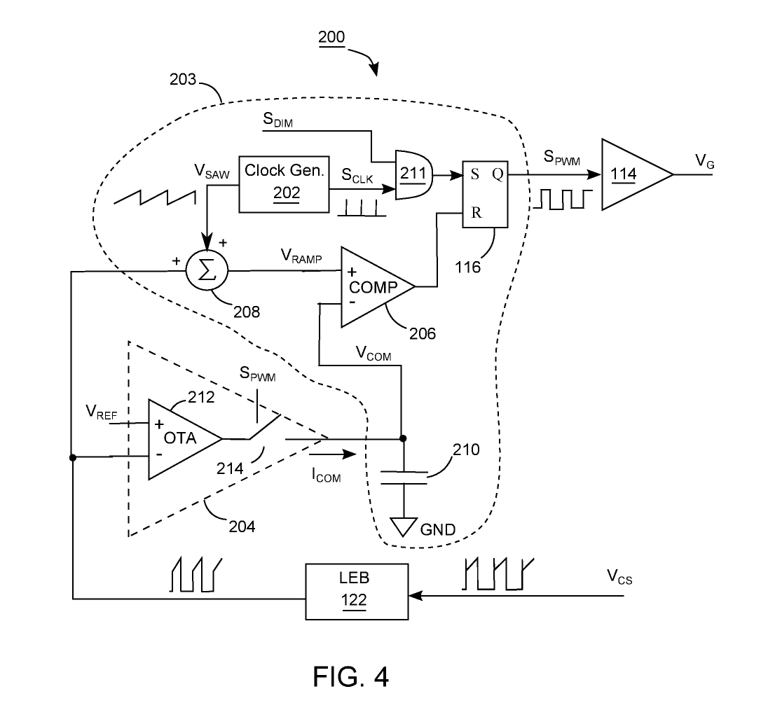

FIG. 4 demonstrates an integrated circuit 200, which is capable of replacing the integrated circuit 102 according to embodiments of the invention.

The integrated circuit 200 includes a pulse-width modulator 203, an amplifier 204, and a leading-ledge blanking circuit 122. The pulse-width modulator 203 includes a clock generator 202, an And gate 211, an SR register 116, an compensation capacitor 210, a comparator 206 and an adder 208.

When the dimming signal S_{DIM} is asserted, “1” in logic, the clock generator 202 provides a clock signal S_{CLK} to periodically set the SR register 116, such that, every certain period of time, the PWM signal S_{PWM} is forced to be “1”, the power switch 104 is turned on via the gate driver 114, and an ON time T_{ON} starts. As an ON time T_{ON} starts, the current IL through the inductor 108 increases in a linear rate. In the opposite when the dimming signal S_{DIM} is deasserted, “0” in logic, the And gate 211 blocks the clock signal S_{CLK}, and the PWM signal S_{PWM} remains “0” in logic to constantly turn OFF the power switch 104.

The non-inverted input of the amplifier 204 receives a reference voltage V_{REF}, and the inverted input receives the current sense signal V_{CS} through the leading-edge blanking circuit 122. The amplifier 204 provides a compensation current signal I_{COM}, which is accumulated or integrated by the compensation capacitor 210 to build up a compensation voltage signal V_{COM}. The amplifier 203 includes an operational transconductance amplifier (OTA) 212 and a switch 214, while the switch is under the control of the PWM signal S_{PWM}. A gm is supposedly to be the differential transconductance gain of the amplifier 204, or I_{COM}=gm*(V_{REF}-V_{CS}). During the ON time T_{ON}, the switch 214 is short and the amplifier 204 is equivalently to be the OTA 212 which, in response to the difference between the reference voltage V_{REF} and the current sense voltage signal V_{CS}, generates the compensation current signal I_{COM} to charge or discharge the compensation capacitor 210. During the OFF time T_{OFF}, however, the switch 214 is open and gm becomes zero because the compensation current signal I_{COM} is zero, so the compensation capacitor 210 holds the compensation voltage signal V_{COM} in the meantime.

The comparator 206 compares the compensation voltage signal V_{COM} to the ramp signal V_{RAMP}. In the embodiment shown in FIG. 4, the ramp signal V_{RAMP} is the summation of the current sense voltage signal V_{CS} and a saw-wave signal V_{SAW} generated from the clock generator 202. The saw-wave signal V_{SAW}, starting from the beginning of the ON time T_{ON}, increases linearly from a default value, and returns back to the default value when a switching cycle ends. The adding of the saw-wave signal V_{SAW} provides slop compensation to prevent sub-harmonic oscillation from happening. Every time when the ramp signal V_{RAMP} exceeds the compensation voltage signal V_{COM}, the comparator 206 resets the SR register 116, making the PWM signal S_{PWM} “0”, so as to end an ON time T_{ON} and start an OFF time T_{OFF}.

In one embodiment, the ramp signal V_{RAMP} could be just the current sense voltage signal V_{CS} without the adding of the saw-wave signal V_{SAW}. In another embodiment, the ramp signal V_{RAMP} could be just the saw-wave signal V_{SAW} without the adding of the current sense voltage signal V_{CS}.

In a steady state, the compensation voltage signal V_{COM} should be a constant every time when the clock signal S_{CLK} sets the SR register 116. As the differential transconductance gain gm of the amplifier 204 is not zero only during ON times T_{ON}, the average of the current sense voltage signal V_{CS} during ON times T_{ON} will be about the same as the reference voltage V_{REF}.

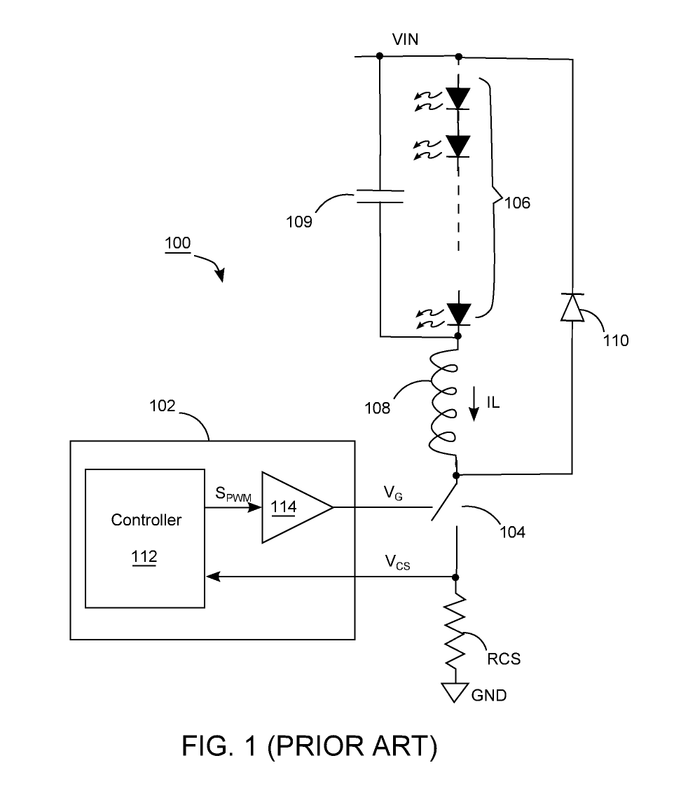

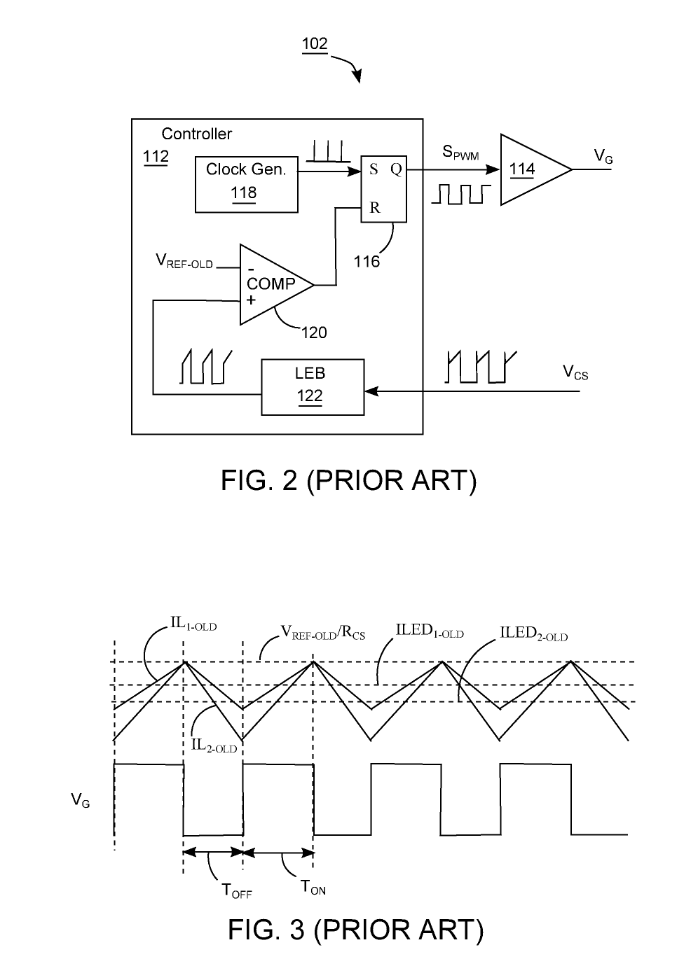

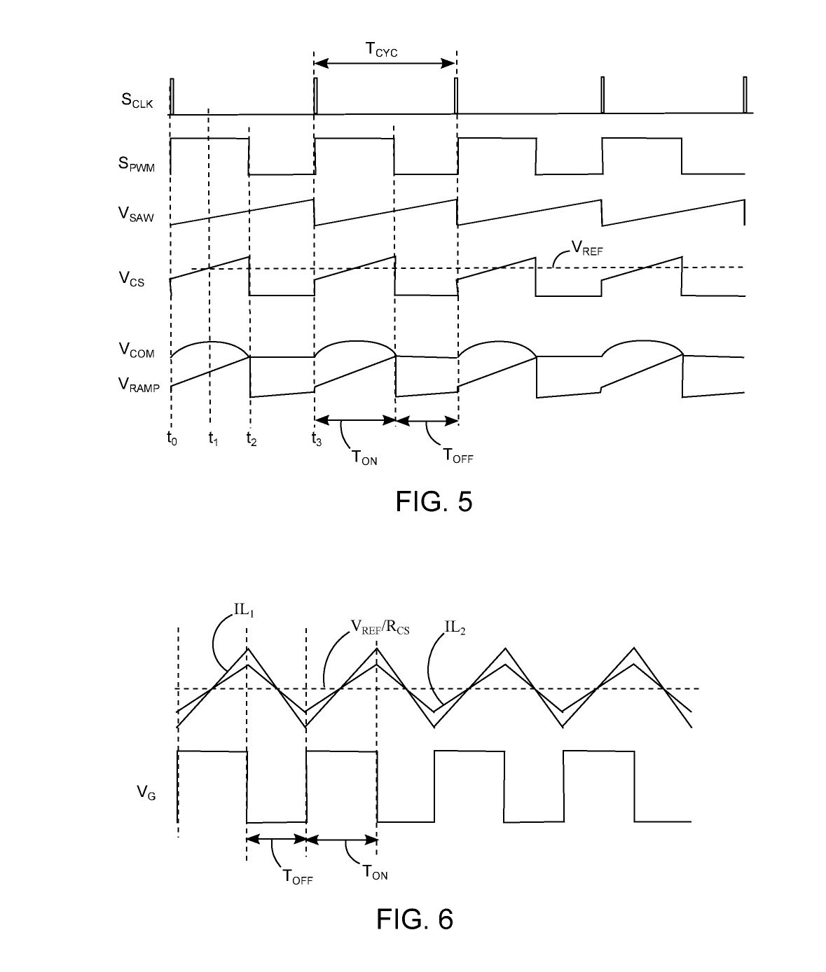

FIG. 5 shows waveforms of some signals in FIG. 4 while the integrated circuit 102 in FIG. 1 is replaced by the integrated circuit 200 in FIG. 4, and the buck converter 100 in FIG. 1 is operated in continuous conduction mode (CCM), which means that a next switching cycle starts when the electromagnetic energy stored in the inductor 108 is not completely depleted. Shown in FIG. 5, a switching cycle T_{CYC} has an ON time T_{ON} and an OFF time T_{OFF}. Some embodiments might have the switching cycle T_{CYC} constant while others have the switching cycle T_{CYC} dependent to the compensation voltage signal V_{COM}. For example, the switching cycle T_{CYC} decreases if the compensation voltage signal V_{COM} increases.

The clock signal S_{CLK} introduces a short pulse to set the SR register 116, starting both an ON time T_{ON} and a switching cycle T_{CYC}. At time t₀ in FIG. 5, the PWM signal S_{PWM becomes “}1” in logic, and the saw-wave signal V_{SAW} ramps up from a default value.

During an ON time T_{ON}, because the power switch 104 is ON, performing a short circuit, the voltage difference between the high-voltage power line VIN and the ground power line GND causes increment in the current IL through the inductor 108. As a result, the current sense voltage signal V_{CS} ramps up linearly over time. At time t₀, the current sense voltage signal V_{CS} is below the reference voltage V_{REF}, so the compensation current signal I_{COM} charges the compensation capacitor 210 to increase the compensation voltage signal V_{COM}.

After time tₗ, the current sense voltage signal V_{CS} exceeds the reference voltage V_{REF}, so the compensation current signal I_{COM} starts to discharge the compensation capacitor 210 and the compensation voltage signal V_{COM} decreases.

As demonstrated in FIG. 5, as the ramp signal V_{RAMP} equals to the summation of the current sense voltage signal V_{CS} and the saw-wave signal V_{SAW}, the ramp signal V_{RAMP} increases over time during an ON time T_{ON}. At time t₂, the ramp signal V_{RAMP} goes to exceed the compensation voltage signal V_{COM}, and this crossover renders the resetting of the SR register 116, making the PWM signal S_{PWM} “0”. Accordingly, the power switch 104 is turned OFF and an OFF time T_{OFF} starts. Meanwhile, as the power switch 104 is suddenly turned OFF, the current sense voltage signal V_{CS} abruptly drops to zero at time t₂ to introduce a drop in the ramp signal V_{RAMP}.

During an OFF time T_{OFF}, the switch 214 within the amplifier 204 is OFF, performing an open circuit, such that both the compensation current signal I_{COM} and the effective differential transconductance gain of the amplifier 204 are about 0. Not being discharged or charged, the compensation capacitor 210 holds the compensation voltage signal V_{COM}, until the beginning of the next switching cycle.

If the buck converter 100 in FIG. 1 has reached a steady state, all signals inside every devices of FIG. 1 must start from their corresponding values or states, and these corresponding values or states do not change from switching cycle to switching cycle. Accordingly, the compensation voltage signal V_{COM} must have the same value at the beginning and the end of a switching cycle. Nevertheless, the compensation current signal I_{COM} is allowed to be not zero only during an ON time T_{ON}, and is in proportion to the difference between the current sense voltage signal V_{CS} and the reference voltage V_{REF}. It implies that the average of the current sense voltage signal V_{CS} will be about the reference voltage V_{REF} in a steady state.

In CCM, the average of the current sense voltage signal V_{CS} is a representative of the average of the current flowing through the inductor 108. FIG. 6 illustrates some results when the buck converter 100 (of FIG. 1) is under the control of the integrated circuit 200 (of FIG. 4), where the current signal IL₁/IL₂ represents the current through the inductor 108 whose inductance is L₁/L₂. As shown in FIG. 6, the average of the current signal IL_{I} and the average of the current signal IL₂ are about the same, each having the value of V_{REF}/R_{CS}, where R_{CS} denotes the resistance of the current sense resistor RCS. The average of the current through the inductor 108 equals to the average of the current through the LED string 106. FIG. 6 means that the average of the current through the LED string 106 is well controlled to be a constant, V_{REF}/R_{CS}, independent from any variation to the inductance of the inductor 108.

It could be derived from the aforementioned teaching that, when FIG. 1 employs the integrated circuit 200 of FIG. 4, the average of the current through the LED string 106 will be also independent from the voltage difference between the high-voltage power line VIN and the ground power line GND.

In FIG. 4, when the dimming signal S_{DIM} is deasserted, the power switch 104 is turned OFF after an ON time T_{ON} and cannot be turned ON because the SR register 116 is set no more. The current through the inductor 108 and the LED string 106 will reduce to 0 soon such that the LED string 106 stops emitting light. Meanwhile, the compensation capacitor 210 holds the compensation voltage signal V_{COM}, whose present value now represents the condition required to make the LED string 106 have the average driving current of V_{REF}/R_{CS}. Once the dimming signal S_{DIM} is asserted later on, the condition memorized by the compensation voltage signal V_{COM} will be used immediately so that the buck converter 100 could quickly convert appropriate power to drive the LED string 106, which, in response, is resumed to emit light soon. In other words, some embodiments of the invention might have a quicker response time to the diming signal S_{DIM}.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An apparatus capable of regulating an average current through a load, the apparatus comprising:
an amplifier having a first input node coupled to receive a first voltage signal representing a current through the load, a second input node coupled to a reference voltage, and a first output node for providing an output signal, wherein the amplifier has a differential gain; and
a pulse-width modulator, for, in response to the output signal, providing a PWM signal to a power switch which controls the current, thereby regulating the average current, wherein the PWM signal is capable of defining an ON time and an OFF time;
wherein, in response to the PWM signal, the differential gain is about 0 during the OFF time.

2. The apparatus as claimed in claim 1, wherein the amplifier is an operational transconductance amplifier providing an output current signal.

3. The apparatus as claimed in claim 1, wherein the amplifier includes an operational transconductance amplifier providing an output current signal at a second output node, the pulse-width modulator includes a compensation capacitor, the amplifier further includes a switch controlled by the PWM signal and connected between the second output node and the compensation capacitor.

4. The apparatus as claimed in claim 1, further comprising a clock generator which periodically starts the ON time.

5. The apparatus as claimed in claim 1, wherein the pulse-width modulator comprises:
a comparator with two inputs coupled to receive the output signal from the amplifier and a ramp signal, respectively.

6. The apparatus as claimed in claim 5, further comprising a clock generator which periodically starts the ON time and provides the ramp signal.

7. The apparatus as claimed in claim 5, further comprising a clock generator which periodically starts the ON time, wherein the ramp signal is in response to the first voltage signal.

8. The apparatus as claimed in claim 7, wherein the ramp signal is generated in response to the first voltage signal and a saw-wave signal provided by the clock generator.

9. The apparatus as claimed in claim 1, wherein the ON time ends and the OFF starts when the ramp signal exceeds the output signal.

10. The apparatus as claimed in claim 1, further comprising:
the power switch controlled by the PWM signal;
an inductive device connected in series with the load between a high-voltage power line and the power switch; and
a discharge diode connected between the power switch and the high-voltage power line.

11. The apparatus as claimed in claim 1, further comprising:
the power switch controlled by the PWM signal; and
a current sense resistor connected between the power switch and a ground power line, for providing the first voltage signal.

12. The apparatus as claimed in claim 1, further comprising a filter capacitor connected in parallel to the load.

13. The apparatus as claimed in claim 1, wherein the pulse-width modulator is controlled by a dimming signal, which keeps the PWM signal at a constant state defining the OFF time when the dimming signal is deasserted.

14. A control method for regulating an average current through a load, comprising:
receiving a first voltage signal representing a current through the load;
providing a reference voltage;
generating an output current signal based on a differential transconductance gain and a difference between the first voltage signal and the reference voltage;
generating a PWM signal in response to the output current signal to regulate the average current, wherein the PWM signal is capable of defining an ON time and an OFF time; and
making the differential transcoductance gain about 0 during the OFF time.

15. The control method as claimed in claim 14, further comprising:
accumulating the output current signal to provide an output voltage signal;
comparing the output voltage signal and a ramp signal; and
starting the OFF time when the ramp signal exceeds the output voltage signal.

16. The control method as claimed in claim 15, comprising:
controlling the PWM signal to periodically start the ON time.

17. The control method as claimed in claim 15, wherein the ramp signal has a saw waveform.

18. The control method as claimed in claim 15, comprising:
providing a saw-wave signal; and
providing the ramp signal in response to the first voltage signal and the saw-wave signal.

19. The control method as claimed in claim 14, comprising:
connecting the load and an inductive device in between a high-voltage power line and a power switch;
providing the PWM signal to the power switch; and
connecting a discharge diode between the power switch and the high-voltage power line.

20. The control method as claimed in claim 14, further comprising:
providing the PWM signal to a power switch; and
connecting a current sense resistor between the power switch and a ground power line;
wherein the current sense resistor provides the first voltage signal.
